(19) United States
(12) Patent Application Publication
(10) Pub. No.: US 2014/0099480 A1
(43) Pub. Date: Apr. 10, 2014

(54) REGISTRATION SYSTEM FOR PHOTOTOOLS

(71) Applicant: RAINBOW TECHNOLOGY SYSTEMS LTD, Glasgow (GB)

(72) Inventors: Charles Jonathan Kennett, Glasgow (GB); John Cunningham, Glasgow (GB)

(21) Appl. No.: 13/839,911

(22) Filed: Mar. 15, 2013

(30) Foreign Application Priority Data
Oct. 8, 2012 (GB) GB1217991.7

(51) Int. Cl. G03F 7/20

(52) U.S. Cl. CPC G03F 7/2014
USPC 428/195.1; 355/72

(57) ABSTRACT

There is herein described a method and apparatus for positioning a phototool. More particularly, there is described a method and apparatus for accurately positioning a phototool capable of photoimaging a substrate (e.g. a web) covered with a wet curable photopolymer wherein the phototool creates an imaged substrate which is used to form images suitable for forming electrical circuits such as for printed circuit boards (PCBs), flat panel displays and flexible circuits.

### FIELD OF THE INVENTION

The present invention relates to a method and apparatus for positioning a phototool. More particularly, the present invention relates to a method and apparatus for accurately positioning a phototool capable of photoimaging a substrate (e.g. a web) covered with a wet curable photopolymer wherein the phototool creates an imaged substrate which is used to form images suitable for forming electrical circuits such as for printed circuit boards (PCBs), flat panel displays and flexible circuits.

### BACKGROUND OF THE INVENTION

In the field of lithographic printing (e.g. printed circuit boards) there is often a need to position a phototool in exact registration with a substrate being printed. This might be for the alignment of tracking and ‘pads’ around holes and other features. Another example where registration is needed is so that an image on the reverse side of a printed circuit board is in close registration with the image on the front side. Generally, more accurate registration leads to improved imaging.

There are several known registration systems. One way is to punch close tolerance holes in the phototool such that the holes and the image are exactly aligned with a second phototool. If the phototools are then pinned with an accurate pin through the holes the phototools will then be held in close alignment. Sometimes the pins are arranged such that they pass through the substrate being printed and the front and back phototool so that the entire package is then in the required registration.

In some cases the phototools are held in a glass ‘book’ such that when the book is closed with the circuit board inside it, everything is in registration. Again the common way to do this is using holes and pins. The problems with these types of systems are that the accuracy of the holes and the pins dictate what the overall alignment is. Often there is wear and tear because the pins have been repeatedly inserted and removed from the hole in a polyester phototool—which is then mechanically degraded resulting in mis-registration.

The inventors of the present application have developed a new type of photoimaging process as described in WO2010/007405, which is incorporated herein by reference. The described process relates to using a resist that is different to pre-dated prior art resists in that it is made up of 100% solids so has no solvents involved in the related processing. In this process, the ink is coated on a panel but is not cured prior to imaging but is sandwiched under a layer of clear film. During exposure to UV light the resist hardens in the exposed areas only. After imaging, the protective polyester is peeled off for re-use and the unexposed (liquid) resist is washed off the panel. However, a problem that exists in this process is that there is a need to accurately register a phototool (both sides) and the substrate being printed. As the process of printing requires the easy removal of the phototool as the board is being printed the normal hole and pin system will not work as removal of the pins would normally have to be at right angles to avoid damaging the polyester phototool. This is not possible in this printing method.

It is an object of at least one aspect of the present invention to obviate or mitigate at least one or more of the aforementioned problems.

It is a further object of at least one aspect of the present invention to provide an improved method and apparatus for positioning a phototool during a photoimaging process.

It is a yet further object of at least one aspect of the present invention to provide an improved method and apparatus for positioning a substrate during a photoimaging process.

### SUMMARY OF THE INVENTION

According to a first aspect of the present invention there is provided a positioning apparatus for a phototool, said positioning apparatus comprising:

a first carrier member comprising at least one annular shaped member;

a second carrier member comprising at least one position locating ball capable of being received in the at least one annular shaped member located on the first carrier member;

a phototool connected to either the first or second carrier member;

wherein the first carrier member is capable of being clamped against the second carrier member and the at least one annular shaped member is capable of receiving the least one position locating ball to provide accurate positioning of the phototool.

The present invention therefore relates to an apparatus for accurately positioning at least one phototool during a photoimaging process.

Typically, there may be phototools connected to both the first and second carrier members which may be brought together as the first and second carrier member are moved into a closed configuration.

The phototools may depend substantially vertically down from the first and second carrier members.

The first and second carrier members may therefore be clamped against one another in a closed configuration using any suitable mechanical and/or spring activated arrangement.

The apparatus therefore comprises a positioning mechanism where a position locating ball (e.g. a ball bearing) on the second carrier member fits at least partly into an annular shaped member located on the first carrier member. The position locating ball may be connected via a connecting arm to a base member connected to the second carrier member.

The at least one annular shaped member located on the first carrier member may be in the form of a bush (e.g. a ball bearing bush) which may function as a seat for the position locating ball.

The diameter of the at least one annular shaped member located on the first carrier member may be slightly less than the diameter of the position locating ball so that the position locating ball is capable of being securely held by the confines of the annular shaped member without actually becoming fully inserted into the at least one annular shaped member. The position locating ball and the annular shaped member may therefore interlock with one another and therefore form a registration and/or positioning system to accurately align phototools against one another. The position locating ball may therefore sit flush against the upper surface of annular shaped member in a precise and pre-determined position.

There may be any suitable number such as two or more position locating balls on the second carrier member to facilitate the positioning of the phototools. In particular embodiments, there may be three position locating balls on the second carrier member which may be in a triangular arrangement which aids in the accurate placement and/or registration of the first and second carrier members onto one another and hence the phototools. The position locating balls may therefore fit into respective annular shaped members (e.g. bushes) located on the first carrier member.

In the photoimaging process according to the present invention a substrate to be imaged may be positioned between phototools using a similar process by using position locating balls and respective annular shaped members within which they are capable of being received. The substrate being imaged may therefore also be accurately positioned prior to photoimaging thereby providing a very accurate and precise photoimaging process.

The positioning apparatus of the present invention may be used in a photoimaging process where a liquid wet photopolymer is deposited (e.g. with a spray, a brush, a roller and/or a dip coating system) onto a substrate and thereafter a thin UV transparent film. Without drying the photopolymer, the liquid wet photopolymer may then be imaged using phototools which are positioned using position locating balls as described above and cured using a radiation source such as any suitable UV radiation source (e.g. a UV lamp or LEDs). After the photoimaging process, liquid photopolymer which has not been exposed to UV radiation is removed using, for example, an aqueous alkali solution via a washing procedure. A standard chemical etching process may then be used. For example, acid or alkali may be used to produce a dielectric substrate containing the required metal (e.g. copper) circuitry covered by polymerised photopolymer. The polymerised photopolymer can then be removed to yield a substrate with the required electrical conductive circuitry.

The apparatus as described in the present invention can also be fully contained in a mini-clean room which therefore provides significant cost savings in the photoimaging process.

Using the method as described in the present invention channels or traces in the form of high definition fine lines or tubes suitable for electrical circuitry are obtained. The fine lines or tubes may have a width or diameter of any of the following: less than or equal to about 200 μm; less than or equal to about 150 μm; less than or equal to about 140 μm; less than or equal to about 130 μm; less than or equal to about 120 μm; less than or equal to about 110 μm; less than or equal to about 100 μm; less than or equal to about 90 μm; less than or equal to about 80 μm; less than or equal to about 75 μm; less than or equal to about 70 μm; less than or equal to about 60 μm; less than or equal to about 50 μm; less than or equal to about 40 μm; less than or equal to about 30 μm; less than or equal to about 20 μm; less than or equal to about 10 μm; or less than or equal to about 5 μm. Alternatively the fine lines or tubes may have a width or diameter of any of the following: about 0.1-200 μm; about 1-150 μm; about 1-100 μm; about 20-100 μm or about 5-75 μm. The fine lines or tubes may be used in conjunction with PCBs and other electrical components.

The process in the present invention may be used to form a variety of electronic components including that of printed circuit boards (PCBs), flat panel displays and flexible circuits suitable for manufacture within the reel to reel market.

There are a number of advantages in the positioning apparatus according to the present invention:
1. The easy availability of ball bearings and bushes made to precision tolerances.
2. The mating members (e.g. position locating balls and the annular shaped member) do not need to be perfectly aligned as they are presented to each other—unlike prior art pin and hole systems.
3. The position locating balls (e.g. ball bearings) have a tendency to sink into the lowest position in the respective annular shaped member (e.g. the bush) as they are pressed together which results in the position locating ball locating very accurately in the centre of the annular shaped member.
4. There is very high repeatability in this process.
5. Using a triangulation of three position locating balls and annular shaped members the positional accuracy can be as good as +/−3 microns. This is far superior to conventional pin and hole systems.
6. When the photoimaging exposure (operation) is complete the apparatus simply falls apart when the clamping pressure is released—so no complicated action to disassemble.
7. The assembly allows seamless separation of phototools and a substrate panel which would not be possible using pins and holes.
8. There is very little wear and tear with this system.

The present invention therefore relates to a method of photoimaging a substrate covered with a wet curable photopolymer (i.e. a wet resist), wherein the photoimaged substrate may be used to form electrical circuits such as PCBs, flat panel displays and flexible circuits. The present invention may also relate to forming dielectric images on dielectrics. In contrast to many prior art techniques, the present invention therefore relates to the use of wet films rather than expensive dry films such as Riston (Trade Mark). Dry films are considerably more expensive than the use of wet films. The use of wet films also overcomes the need for curing of the wet films and therefore leads to a very controllable process.

According to a second aspect of the present invention there is provided photoimaged substrates formed according to the first aspect.

The photoimaged substrates may be used to form photoimaged circuits.

Typically, the photoimaged circuits may be electrical circuits which may be used in the manufacture of, for example, PCBs, flat panel displays and flexible circuits.

According to a third aspect of the present invention there is provided a method of accurately positioning a phototool, said method comprising:

providing a first carrier member comprising at least one annular shaped member;

providing a second carrier member comprising at least one position locating ball capable of being received in the at least one annular shaped member located on the first carrier member;

a phototool connected to either the first or second carrier member;

wherein the first carrier member is capable of being clamped against the second carrier member and the at least one annular shaped member is capable of receiving the least one position locating ball to provide accurate positioning of the phototool.

The apparatus for performing the positioning of the phototool may be as defined in the first aspect.

### BRIEF DESCRIPTION OF THE DRAWINGS

Embodiments of the present invention will now be described, by way of example only, with reference to the accompanying drawings in which:

FIG. 1 is a perspective view of positioning apparatus in a closed configuration according to an embodiment of the present invention;

FIG. 2 is a sectional side view of the positioning apparatus in the closed configuration shown in FIG. 1;

FIG. 3 a perspective view of the positioning apparatus in an open configuration shown in FIGS. 1 and 2;

FIG. 4 is a perspective view of the other side of the positioning apparatus in the open configuration shown in FIG. 3; and

FIG. 5 is a sectional side view of the positioning apparatus in the open configuration shown in FIGS. 3 and 4.

### BRIEF DESCRIPTION

Generally speaking, the present invention resides in the provision of an improved method and apparatus for positioning a phototool and/or a substrate.

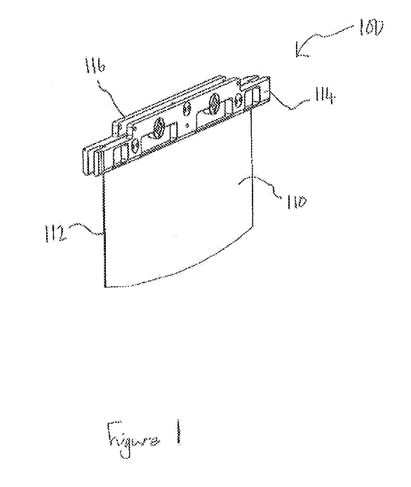

FIG. 1 is a representation of positioning apparatus according to the present invention generally designated 100. As shown in FIG. 1 the positioning apparatus 100 is in a closed configuration and comprises a first carrier member 114 and a second carrier member 116 which may be clamped and attached to one another via a positioning mechanism which will be described in more detail below. By clamping and attaching the first and second carrier members 114, 116 together has the function of bringing two separate phototools 110, 112 together.

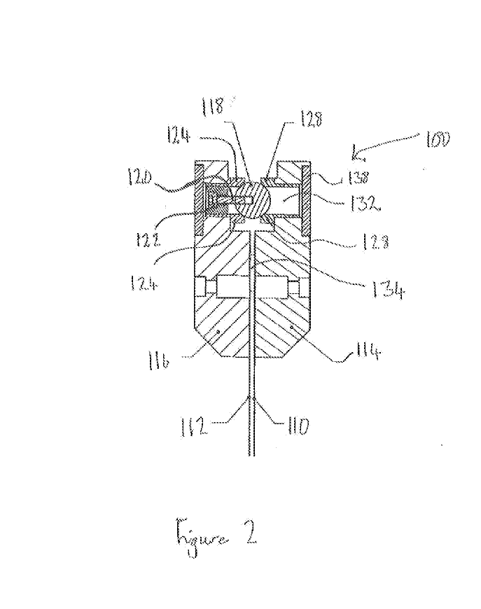

FIG. 2 is a sectional side view of the positioning apparatus 100 which shows the positioning mechanism. The positioning mechanism comprises a position locating ball 118 (e.g. a ball bearing). The position locating ball 118 is attached via a connecting arm 120 to a base member 122 connected to the second carrier member 116. As shown in FIG. 2 the position locating ball 118 resides in an annular shaped member 124 which protrudes from the second carrier member 116. In FIG. 2 the positioning apparatus 100 is in a closed position and the position locating ball 118 is shown to be held within an annular shaped member 128 which protrudes from the first carrier member 114. The position locating ball 118 is therefore securely held in place. The annular shaped member 128 may be in the form of a bush (e.g. a ball bearing bush). There is a cylindrical cavity 132 located within the annular shaped member 128 and in front of a base member 138. The diameter of the cylindrical cavity 132 is slightly less than the diameter of the position locating ball 118 so that the position locating ball 118 is capable of being securely held by the confines of the annular shaped member 128 without actually becoming fully inserted into the cavity 132. The position locating ball 118 and the annular shaped member 128 may therefore interlock with one another and therefore form a registration and/or positioning system to accurately align phototools 110, 112 against one another. The position locating ball 118 may therefore sit flush against the upper surface of annular shaped member 128 in a precise and pre-determined position.

Both the position locating ball 118 and the annular shaped member 128 (e.g. a bush) are very accurate components and when one is pressed against the other the position locating ball 118 tends to self align in the centre of the annular shaped member 128.

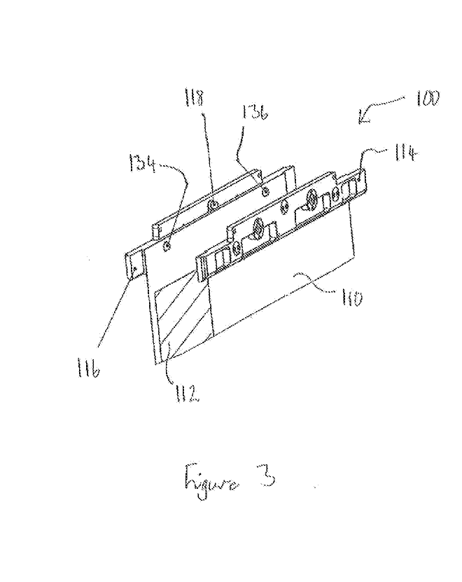

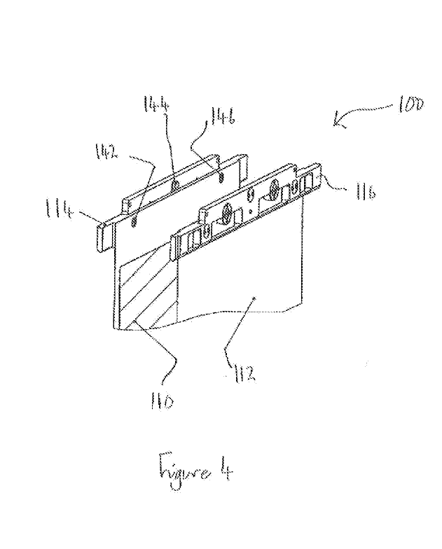

FIG. 3 is a view of the positioning apparatus 100 in an open configuration which shows that there are three position locating balls 118, 134, 136 located on the second carrier member 116. The three position locating balls 118, 134, 136 are located in a triangular arrangement which aids in the accurate placement and registration of the first and second carrier member 114, 116 onto one another and hence the phototools 110,112. There may be any suitable number of position locating balls. The position locating balls 118, 134, 136 fit into annular shaped members 142, 144, 146 located on the first carrier member 114. The annular shaped members 142, 144, 146 are clearly shown in FIG. 4.

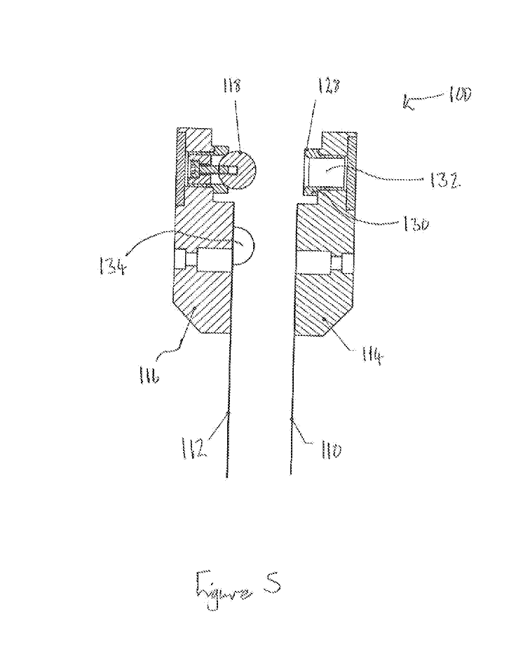

FIG. 5 is a sectional view of the positioning apparatus 100 in an open configuration. The position locating ball 118 is shown as well as another position locating ball 134 (the third another position locating ball is located behind ball 134).

The positioning apparatus 100 of the present invention may be used in a photoimaging process where a liquid wet photopolymer is deposited (e.g. with a spray, a brush, a roller and/or a dip coating system) onto a substrate. Without drying the photopolymer, the liquid wet photopolymer may then be imaged using the phototools 110, 112 and cured using a radiation source such as any suitable UV radiation source (e.g. a UV lamp or LEDs). Although not shown a substrate being imaged between the phototools 110, 112 may have a similar positioning mechanism using position locating balls and respective annular shaped members within which they are received. The substrate being imaged may therefore also be accurately positioned prior to photoimaging thereby providing a very accurate and precise photoimaging process. After the photoimaging process, liquid photopolymer which has not been exposed to UV radiation is removed using, for example, an aqueous alkali solution via a washing procedure. A standard chemical etching process may then be used. For example, acid or alkali may be used to produce a dielectric substrate containing the required metal (e.g. copper) circuitry covered by polymerised photopolymer. The polymerised photopolymer can then be removed to yield a substrate with the required electrical conductive circuitry.

The apparatus 100 as described in the present invention can also be fully contained in a mini-clean room which therefore provides significant cost savings in the photoimaging process.

Using the method as described in the present invention channels or traces in the form of high definition fine lines or tubes suitable for electrical circuitry are capable of being obtained. The fine lines or tubes may have a width or diameter of any of the following: less than or equal to about 200 μm; less than or equal to about 150 μm; less than or equal to about 140 μm; less than or equal to about 130 μm; less than or equal to about 120 μm; less than or equal to about 110 μm; less than or equal to about 100 μm; less than or equal to about 90 μm; less than or equal to about 80 μm; less than or equal to about 75 μm; less than or equal to about 70 μm; less than or equal to about 60 μm; less than or equal to about 50 μm; less than or equal to about 40 μm; less than or equal to about 30 μm; less than or equal to about 20 μm; less than or equal to about 10 μm; or less than or equal to about 5 μm. Alternatively the fine lines or tubes may have a width or diameter of any of the following: about 0.1-200 μm; about 1-150 μm; about 1-100 μm; about 20-100 μm or about 5-75 μm. The fine lines or tubes may be used in conjunction with PCBs and other electrical components.

The process in the present invention may be used to form a variety of electronic components including that of printed circuit boards (PCBs), flat panel displays and flexible circuits.

Whilst specific embodiments of the present invention have been described above, it will be appreciated that departures from the described embodiments may still fall within the scope of the present invention. For example, any suitable type of position locating ball and annular shaped members may be used to provide accurate positioning and placement of phototools and/or substrates. Moreover, the apparatus of the present invention may also be used for other types of accurate positioning and placement.

1. Positioning apparatus for a phototool, said positioning apparatus comprising:
a first carrier member comprising at least one annular shaped member;
a second carrier member comprising at least one position locating ball capable of being received in the at least one annular shaped member located on the first carrier member;
a phototool connected to either the first or second carrier member;
wherein the first carrier member is capable of being clamped against the second carrier member and the at least one annular shaped member is capable of receiving the least one position locating ball to provide accurate positioning of the phototool.

2. Positioning apparatus for a phototool according to claim 1, wherein there are phototools connected to both the first and second carrier members which are capable of being brought together as the first and second carrier members are moved into a closed configuration.

3. Positioning apparatus for a phototool according to claim 2, wherein the phototools depend substantially vertically down from the first and second carrier members.

4. Positioning apparatus for a phototool according to any preceding claim, wherein the first and second carrier members are capable of being clamped against one another in a closed configuration using any suitable mechanical and/or spring activated arrangement.

5. Positioning apparatus for a phototool according to any preceding claim, wherein the apparatus comprises a positioning mechanism where a position locating ball (e.g. a ball bearing) on the second carrier member fits at least partly into an annular shaped member (e.g. a ball bearing bush) located on the first carrier member.

6. Positioning apparatus for a phototool according to any preceding claim, wherein the position locating ball is connected via a connecting arm to a base member connected to the second carrier member.

7. Positioning apparatus for a phototool according to any preceding claim, wherein the least one annular shaped member located on the first carrier member is in the form of a bush (e.g. a ball bearing bush) which is capable of functioning as a seat for the position locating ball.

8. Positioning apparatus for a phototool according to any preceding claim, wherein the diameter of the at least one annular shaped member located on the first carrier member is slightly less than the diameter of the position locating ball so that the position locating ball is capable of being securely held by the confines of the annular shaped member without actually becoming fully inserted into the at least one annular shaped member.

9. Positioning apparatus for a phototool according to any preceding claim, wherein the position locating ball and the annular shaped member are therefore capable of interlocking with one another and therefore forming a registration and/or positioning system to accurately align phototools.

10. Positioning apparatus for a phototool according to any preceding claim, wherein the position locating ball is capable of sitting flush against the upper surface of annular shaped member in a precise and pre-determined position.

11. Positioning apparatus for a phototool according to any preceding claim, wherein there are two or more position locating balls on the second carrier member to facilitate the positioning of the phototools which fit into respective annular shaped members (e.g. bushes) located on the first carrier member.

12. Positioning apparatus for a phototool according to any preceding claim, wherein there are three position locating balls located on the second carrier member which are located in a triangular arrangement which fit into respective annular shaped members (e.g. bushes) located on the first carrier member.

13. Positioning apparatus for a phototool according to any preceding claim, wherein a substrate to be imaged is capable of being positioned between phototools using position locating balls and respective annular shaped members within which they are capable of being partly received.

14. Positioning apparatus for a phototool according to any preceding claim, wherein the positioning apparatus is capable of being used in a photoimaging process where a liquid wet photopolymer is deposited (e.g. with a spray, a brush, a roller and/or a dip coating system) onto a substrate and without drying the photopolymer laying down a thin UV transparent film, the liquid wet photopolymer is then imaged using phototools which are positioned using position locating balls.

15. Positioning apparatus for a phototool according to claim 14, wherein the photoimaging process uses a radiation source such as any suitable UV radiation source (e.g. a UV lamp or LEDs) and after the photoimaging process, liquid photopolymer which has not been exposed to UV radiation is removed using, for example, an aqueous alkali solution via a washing procedure.

16. Positioning apparatus for a phototool according to any preceding claim, wherein the apparatus is capable of being used in a photoimaging process to form channels or traces in the form of high definition fine lines or tubes suitable for electrical circuitry are obtained.

17. Positioning apparatus for a phototool according to claim 16, wherein the fine lines or tubes have a width or diameter of any of the following: less than or equal to about 200 μm; less than or equal to about 150 μm; less than or equal to about 140 μm; less than or equal to about 130 μm; less than or equal to about 120 μm; less than or equal to about 110 μm; less than or equal to about 100 μm; less than or equal to about 90 μm; less than or equal to about 80 μm; less than or equal to about 75 μm; less than or equal to about 70 μm; less than or equal to about 60 μm; less than or equal to about 50 μm; less than or equal to about 40 μm; less than or equal to about 30 μm; less than or equal to about 20 μm; less than or equal to about 10 μm; or less than or equal to about 5 μm.

18. Positioning apparatus for a phototool according to any preceding claim, wherein the apparatus is capable of being used to form a variety of electronic components including that of printed circuit boards (PCBs), flat panel displays and flexible circuits.

19. Photoimaged substrates formed using the apparatus as defined in any of claims 1 to 18.

20. A method of accurately positioning a phototool, said method comprising:
providing a first carrier member comprising at least one annular shaped member;
providing a second carrier member comprising at least one position locating ball capable of being received in the at least one annular shaped member located on the first carrier member;
a phototool connected to either the first or second carrier member;
wherein the first carrier member is capable of being clamped against the second carrier member and the at least one annular shaped member is capable of receiving the least one position locating ball to provide accurate positioning of the phototool.

21. Apparatus for accurately positioning a phototool and/or a substrate to be photoimaged as hereinbefore described and/or as shown in FIGS. 1 to 5.

22. A method for accurately positioning a phototool and/or a substrate as hereinbefore described and/or as shown in FIGS. 1 to 5.
